(19) United States
(12) Patent Application Publication
(10) Pub. No.: US 2003/0046631 A1
(43) Pub. Date: Mar. 6, 2003

(54) Error correction scheme for use in flash memory allowing bit alterability

(76) Inventors: Steffen Gappisch, Zurich (CH); Constant Paul Marie Jozef Baggen, Eindhoven (NL); Andre Guilliaume Joseph Slenter, Eindhoven (NL); Hans-Joachim Gelke, Zurich (CH)

Correspondence Address: U.S. Philips Corporation, 580 White Plains Road, Tarrytown, NY, 10591, US

(21) Appl. No.: 10/127,530

(22) Filed: Apr. 22, 2002

(30) Foreign Application Priority Data
Apr. 24, 2001 (EP) 01109905.8

(51) Int. Cl. G11C 29/00

(52) U.S. Cl. 714/763

(57) ABSTRACT

A system (70) comprising a microprocessor (74), a data bus (75) for writing data into a Flash memory device (71) and a data bus (75) for reading data from the Flash memory device (71). The Flash memory device (71) comprises an error correction encoder (72), a Flash memory (71), an error correction decoder (73), and a Flash data bus (75) for interconnecting the error correction encoder (72), the Flash memory (71), and the error correction decoder (73). The data, when being processed by the error correction encoder (72) are converted into a word that comprises a status word (51), a data word (52), and a redundancy word (53). This approach enables error correction with single-bit alterability.

### FIELD OF THE INVENTION

The present invention relates to the field of flash memory devices. More particularly, the present invention concerns an error correction scheme that enables bit alterability of Flash memories.

### BACKGROUND OF THE INVENTION

Many of today's consumer and embedded system products usually comprise three different types of memory parts used to support the required features of the product. For example, in a typical cellular telephone, a Flash memory part is used for code storage, SRAM provides the stack and volatile data storage, while a third part, that is, an EEPROM device, provides non-volatile storage for data that are frequently updated or changed. The content of these three data groups change at different rates and at different times, depending on the type of product. Obviously, all of this data needs to be stored where it can be best retrieved as well as changed.

A Flash memory is used for data storage and retrieval in consumer and industrial applications requiring non-volatile data storage for many years. A Flash memory can for example be used to provide disk emulation to replace a rotating disk. In other words, a Flash memory can be employed as the read/write media in place of a rotating disk.

A method for increasing the data reliability in a Flash memory device is disclosed in U.S. Pat. No. 6,041,001. An error correction code, known as a Hamming code, is employed and the Flash memory cells are subdivided into blocks. Each such block is further divided into sectors. Said US patent focuses on the organization of data in the Flash memory. High power error correction is used to perform error detection and error correction.

A Flash memory is an electrically re-writable nonvolatile digital memory device that does not require a power source to retain its memory contents. A typical Flash memory stores charge on a floating gate to represent a first logic state in the binary state system, while the lack of stored charge represents a second logic state in the binary state system. Additionally, the typical Flash memory device is capable of performing a write operation, a read operation, and an erase operation.

In high-volume consumer applications, Flash memory has been used primarily for code storage, although the in-circuit write capability of Flash allows it to be used for data storage also. Until recently, the inability of Flash to be written (or erased) while at the same time an internally-stored code is being executed, has prevented it from replacing EEPROM parts in certain products. However, the new series Flash parts provides this simultaneous read-while-write (RWW) functionality in a single Flash memory. This feature paves the way for the storage of non-volatile data and executable code in the same Flash device. The ability of this Flash part to provide executable code and store frequently updated data allows for the elimination of EEPROMs in many products. As indicated in FIG. 1A, a conventional product until now typically comprised a Flash memory 10, an EEPROM 11, and an SRAM 12. Future products can be realized where the EEPROM device is removed from products entirely, creating substantial savings as regards chip area and cost of the respective product. An example of such a future product is illustrated in FIG. 1B. It comprises a Flash memory 13 and an SRAM 14.

New product developments make Flash memories with a higher storage capacity necessary. Today, Flash memory capacity is doubling every year. Large Flash memories necessitate the use of error correction in order to reach an acceptable product reliability. Error correction is based on generating redundant bits, i.e., parity bits, which are stored in the memory together with the data bits. Upon reading out the memory, these redundancy bits are used to detect and correct bit errors. Using error correction for Flash memories has one big disadvantage: once a data word is programmed to the Flash memory, this data word cannot be changed anymore without violating the correct generation of the redundancy bits. In other words, the single bit alterability of data words is lost when using conventional error correction schemes.

Usually, Flash memory is employed without any error correction scheme. In these conventional Flash memories one has to erase the whole Flash memory (or at least a substantial part thereof) if one whishes to change one Flash data word.

Error correction is employed in digital memory design to cope with bit errors. Usually, an appropriate logic circuitry is employed that implements an error correction code (ECC). An ECC allows data bits being read or transmitted to be checked for errors and, where necessary, to correct the errors on-the-fly.

Due to the increasing size of the Flash memory that is employed, it becomes more and more important to provide some sort of error correction. Some of the most recent Flash memory systems are equipped with an error correction scheme employing an encoder for writing data into the Flash memory and a decoder for reading data from the Flash memory.

The bit alterability, however, is a very important feature, e.g., when emulating EEPROM functionality on a Flash memory, a technique which is used by all major Flash marketers, e.g., Intel, AMD, Atmel, and others.

It is an object of the present invention to provide a scheme that allows for Flash memory to be used in many of today's and future applications.

It is, therefore, an object of the present invention to provide a scheme that enables bit alterability when emulating EEPROM functionality on a Flash memory.

### SUMMARY OF THE INVENTION

These and other objects are achieved by improvements in the architecture of Flash memories and in the way such Flash memories are being employed.

This invention concerns a scheme where an error correction block applies a coding scheme which makes bit alterability possible on a Flash memory.

In accordance with the present invention a system is provided that comprises a microprocessor, a data bus for writing data into a Flash memory device, and a data bus for reading data from the Flash memory device. The Flash memory device comprises an error correction encoder, a Flash memory, an error correction decoder, and a Flash data bus for interconnecting the error correction encoder, the Flash memory and the error correction decoder. The data, upon processing by the error correction encoder, are converted into a word comprising a status word, a data word, and a redundancy word.

Preferred system implementations are provided in the claims 2-15.

A method is provided for storing data in a Flash memory device, these data being fed to a parity generator that generates a redundancy word and provides this redundancy word at an output. In addition, a status word is generated and the data, the redundancy word and the status word are combined into one word. This word is then written into the Flash memory device where it is stored.

Advantageous methods are claimed in the claims 17-22.

The proposed invention is an enabling technology to make, e.g., EEPROM emulation possible on large Flash memories using error correction.

It is an advantage of the present invention that manufacturers can use the Flash memory parts rather than EEPROM to store executable code and non-volatile data.

It is another advantage of the present invention that it allows EEPROM functionality to be selectively added to a Flash memory array.

### BRIEF DESCRIPTION OF THE DRAWINGS

For a more complete description of the present invention and for further objects and advantages thereof, reference is made to the following description, taken in conjunction with the accompanying drawings, in which:

FIG. 1A is a conventional computing device with a Flash memory, an EEPROM, and an SRAM.

FIG. 1B is a conventional computing device with a Flash memory and an SRAM.

FIG. 2 illustrates the programming of a Flash data word without error correction being applied.

FIG. 3 is a block diagram depicting a known Flash memory with an error correction device.

FIG. 4 illustrates the programming of a Flash data word with error correction being applied.

FIG. 5 is a schematic representation of the organization of a data word in accordance with the present invention.

FIG. 6 illustrates the programming of a Flash data word with error correction according to the present invention being applied.

FIG. 7 is a schematic representation of the data organization for EEPROM emulation on a Flash memory.

FIG. 8 is a block diagram depicting a first embodiment of the present invention.

FIG. 9 is a block diagram depicting a second embodiment of the present invention.

FIG. 10A is a block diagram depicting an error correction encoder in accordance with one embodiment of the present invention.

FIG. 10B is a block diagram depicting an error correction decoder in accordance with one embodiment of the present invention.

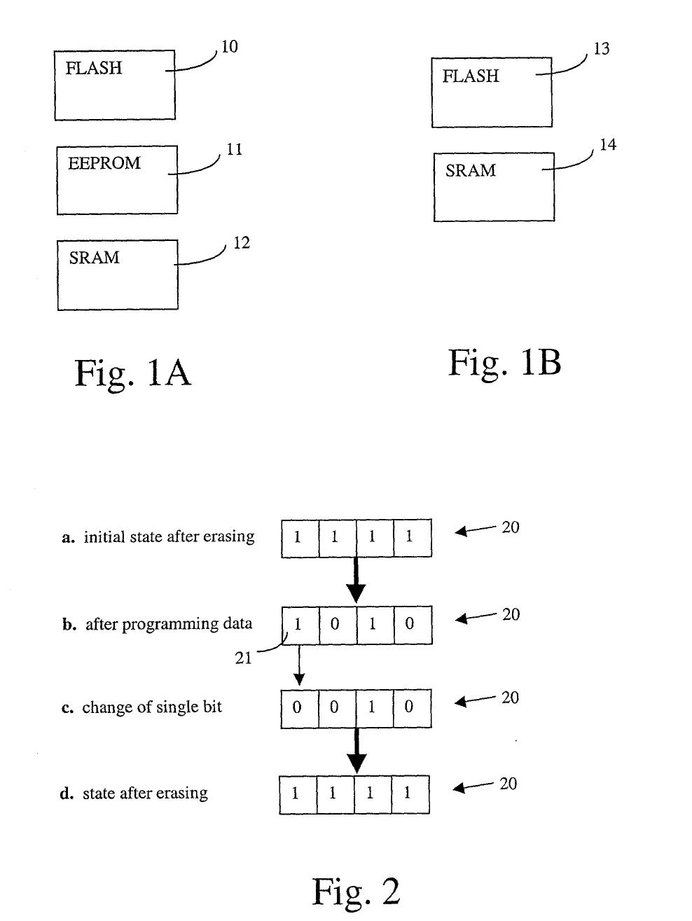

### DESCRIPTION OF PREFERRED EMBODIMENTS

Flash memories, as opposed to other memory types like SRAM, allow bit changes only in one direction. A logic ‘1’ stored in a Flash memory cell can be changed to a logic ‘0’ by a programming operation. Changing a logic ‘0’ by a programming operation into a logic ‘1’, however, is not possible. Changing programmed cells (logic content ‘0’) to the logic state ‘1’ would only be possible with an erase operation. An erase operation cannot be performed on single bits, but only on a larger amount of data (referred to as block erase) or even on the entire memory (referred to as Flash erase).

FIG. 2 depicts a possible data manipulation on a Flash data word 20. In the present example, the Flash data word 20 has four bits. At the beginning (initial state a) all four bits are erased and have therefore the content ‘1’. Subsequently, the data word ‘1010’ is programmed (state b). In a subsequent step (state c) the most significant bit (MSB) 21 is changed from ‘1’ to ‘0’. Finally, the data word 20 is erased (together with many other data words which are not shown in FIG. 2) to the initial value ‘1111’(state d). Such single bit changes are possible as long as the change is from logic ‘1’ to logic ‘0’(1→0).

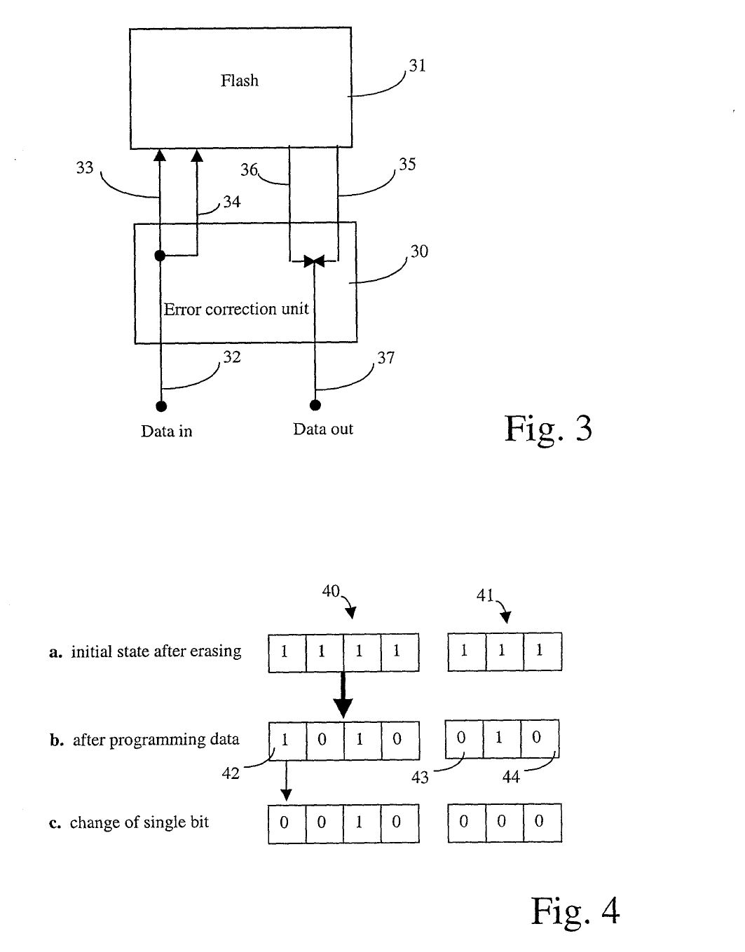

The FIG. 3 shows the application of an error correction block 30 together with a Flash memory 31. Data which should be programmed to the Flash memory 31 are fed via input line 32 (herein called Data in or Din) into the error correction block 30. This error correction block 30 generates redundancy bits. The data and the redundancy bits are programmed together to the Flash memory 31. The data are written into the Flash memory 31 via the line 33 and the redundancy bits via the line 34. During a read operation, the data and the redundancy bits are read from the Flash memory 31 via lines 35 and 36, respectively. The information stored in the redundancy bits is used to detect and correct a possible error in the data word. Finally, the corrected data is output at output line 37 (herein called Data out or Qout).

When a conventional error correction scheme (e.g., a Hamming-Code based scheme)—like the one illustrated in FIG. 4—is used, single bits cannot be changed freely as illustrated in FIG. 4. (State a.) After erasing the content of the memory, the Flash data word 40 and the redundancy bits 41 are in an initial state. That is, all bits (data and redundancy bits) are logic ‘1’. (State b.) When the data word 40 is programmed, the redundancy bits 41 are programmed as well according to an appropriate error correction scheme. Well suited is an Error Correcting Code such as, for example, the Hamming code. The Hamming code may be used to detect and correct single bit errors and double bit errors, where a double bit error indicates that two distinct data bits contain errors.

(State c.) It will be found that the MSB 42 of the data word 40 can still be changed from a logic ‘1’ to a logic ‘0’. But the redundancy bits 41 cannot be changed accordingly, since this would require two changes from a logic ‘0’ to a logic ‘1’. The MSB 43 and the LSB 44 of the redundancy bits 41 should be changed from logic ‘0’ to logic ‘1’ which is not possible. The result would be an incorrect word in the Flash memory. This example demonstrates that the single bit alterability is lost when Flash memory is used together with the conventional coding algorithms like the Hamming code. When a conventional error correction scheme is used, single bits cannot be changed freely as was illustrated in FIG. 4.

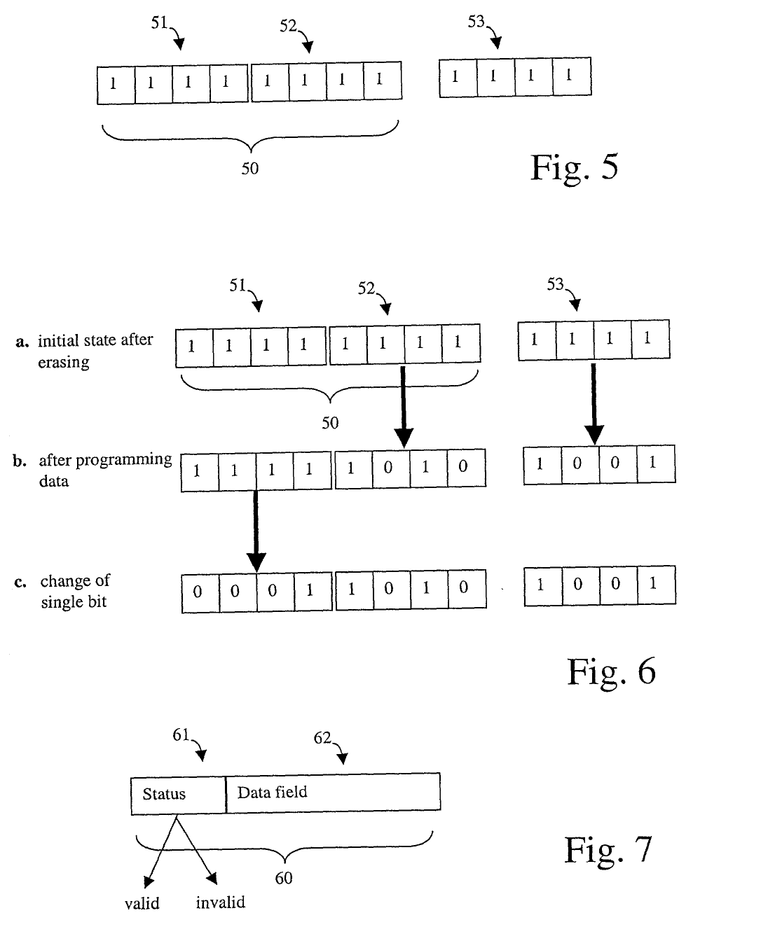

According to the present invention, a new error correction scheme is proposed which enables an improved bit alterability on Flash data words. FIG. 5 depicts the organization of a Flash data word 50 with the coding scheme according to the present invention. As illustrated in FIG. 5, the Flash data word 50 is divided into two sections 51 and 52. In the given example, the four most significant bits 51 of the data word 50 are reserved for bit changes. The remaining four bits 52 of the data word 50 are used for random data. The use of the redundancy bits 53 is the same as in conventional coding schemes. Note, however, that a longer redundancy word 53 is necessary since due the introduction of the word 51 the whole Flash data word 50 is longer. Please note that usually the section 52 of the Flash data word 50 would be longer than the section 51.

FIG. 6 illustrates in detail the principle of the new coding scheme: (State a) after an erase operation all bits of the Flash data word 50 and the redundancy word 53 are logic ‘1’. (State b) Data are programmed to the data part 52 of the Flash data word 50. In the example shown, the data ‘1010’ are programmed. The part 51 reserved for single bit changes is, for the time being, left untouched. The redundancy word 53 is programmed to ‘1001’. (State c) Now a modification is done on the Flash data word 50 by programming the data field 51 reserved for bit changes to ‘0001’. The new Flash data word 50 is ‘0001 1010’ which has the same redundancy word 53 as the old Flash data word ‘111 1010’. As a result, the modification of the Flash data word 50 is correct and a legal code word is obtained upon read out of the Flash memory.

It is to be noted that the bit alterability is restricted. Bits can only be changed within a reserved section of the Flash data word. Furthermore, not all possible bit changes are allowed. In the given example four bits (section 51) are reserved for changes. Theoretically, 16 bit modifications are possible but only two out of these 16 are allowed (e.g., ‘0001’ and ‘0100’). The possible bit changes are herein referred to as ‘magic words’. Since a cyclic coding scheme (cyclic code) is used for the definition of the redundancy word 53, there are certain Flash data words 50 (magic words) that have an identical redundancy word 53.

Details of the present scheme are now addressed in connection with an application example.

The present invention can be applied, for example, in future mobile phone systems, for example. The ever-increasing demand for large Flash memory sizes (64 Mb-128 Mb) makes error correction necessary. To employ Flash memory without an error correction scheme is, therefore, not a viable option. In a cellular phone small amounts of data (parameters) which change frequently (e.g., phone numbers, tax counts, etc.) are typically stored on a dedicated EEPROM chip which allows erasing at the byte level. In order to reduce cost and component count for mobile phones, a new trend is to omit the EEPROM chip and to emulate the EEPROM functionality on the Flash memory. This technique is widely propagated by all major marketers. Unlike EEPROM, the Flash memory cannot be erased at a byte level as discussed in the introductory part of the description. Since a byte in a Flash memory may not be overwritten, an old occurrence of a Flash data word is marked “invalid” when the Flash data word is changed. The updated Flash data word is written to the next available Flash memory location. Typically, Flash management software is employed that tracks the valid occurrence of the Flash data. FIG. 7 shows how the Flash data words 60 are organized when the EEPROM functionality is emulated on a Flash memory. The Flash data word 60 is divided into two fields 61 and 62. In the Flash data field 62, the actual information (random data) can be stored. In the status field 61 a tag is programmed to indicate whether the data contained in the Flash data field 62 are valid or invalid. This application corresponds directly to the invention herein described. The status field 61 requires single bit changes after the Flash data field 62 was already programmed. When an error correction is used, single bit changes to already programmed data are not possible. An error correction according to the new scheme allows bit modifications as needed for an EEPROM emulation.

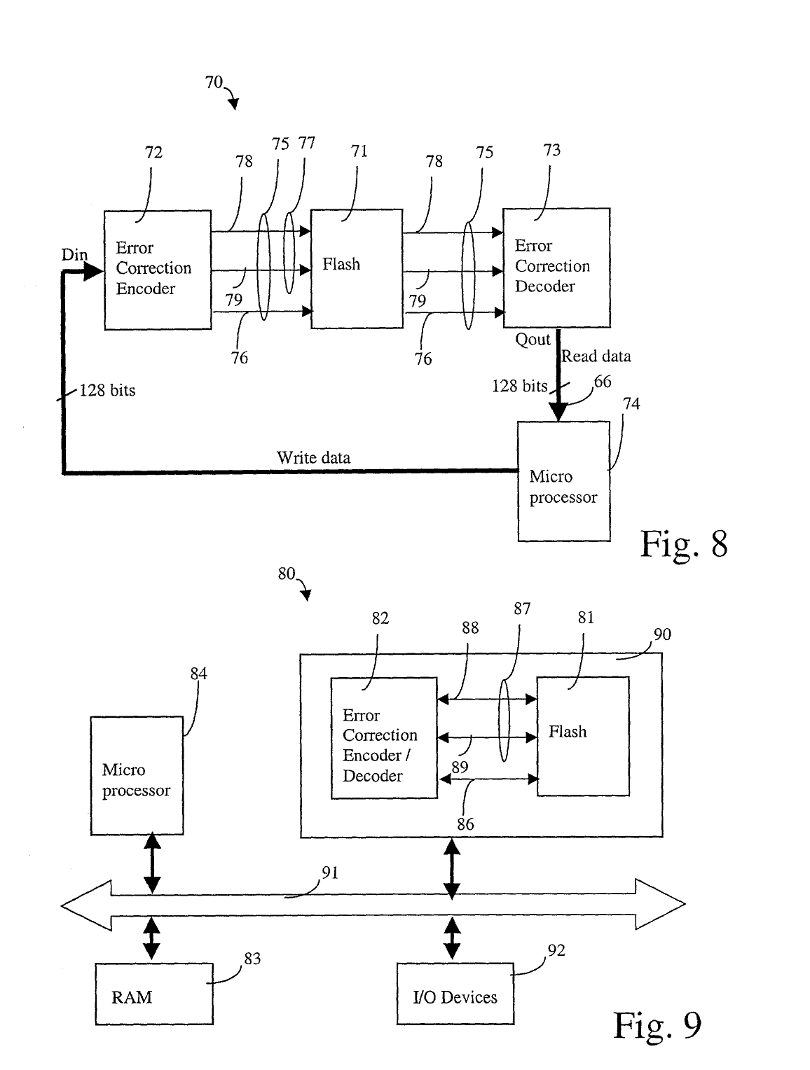

The block diagram of a system 70 in accordance with the present invention is given in FIG. 8. The system 70 is an integrated circuit system with a non volatile Flash memory 71. An error correction encoder 72 is situated at the input side of the Flash memory 71. It uses an error correction algorithm for writing data to the Flash memory 71. At the output side of the Flash memory 71 an error correction decoder 73 is situated for reading stored bits from the Flash memory 71. Furthermore, the system 70 comprises a microprocessor 74. A Flash data bus 75 connects the error correction encoder 72 to the Flash memory 71 and the Flash memory 71 to the error correction decoder 73. The Flash data bus 75 is divided into bit lines 76 carrying the redundancy bits and bit lines 77 carrying the Flash data bits. The data bit lines 77 are divided into bit lines 78 carrying the status bits and bit lines 79 carrying the data bits. According to the present invention, the error correction encoder 72 does not change the assembly of the redundancy bits if the status bits are changed to certain predefined values (“magic words”).

If the data word that is to be programmed into the Flash memory at the entry Din of the error correction encoder 72 has 128 bits, the Flash data bus 75 preferably is 136 bits wide, a redundancy word of 8 bits, a Flash data word of 112 bits and a status bit word of 16 bits then being transmitted to the Flash memory 71. Vice versa, when a word is read from the Flash memory 71, the redundancy word has 8 bits, the Flash data word 112 bits and the status bit word 16 bits. The data word at the output line 66 is 128 bits wide. In the case of a 128 bit-data word, a 16 bit-status word, and an 8 bit-redundancy word, there are several magic words available. The status word is allowed to take on one of the magic words. No words other than the magic words are allowed. When there are three different 16-bit magic words, the status field can store one of the three magic words. Note that the parity bits according to the present invention still change if the data word in the data field changes. The parity bits do not change, however, if the status information changes from one magic word to another magic word. The software (microcode) that is employed to control the microprocessor, ‘knows’ the magic words. The magic words can be stored, for example, in the Flash memory.

In an integrated circuit system according to another embodiment of the present invention the status bits 61 may be employed to determine whether the data in the content section 62 are valid or not.

In another embodiment of the present invention the Flash memory 71 is employed in a manner that emulates an EEPROM.

In yet another embodiment of the present invention a cyclic redundancy code, preferably a symmetric Hamming code, is employed as an error correction algorithm in the integrated circuit system 70.

A further embodiment of the present invention is given in FIG. 9. The system 80 comprises a microprocessor 84, a microprocessor bus 91, a RAM 83, I/O devices 92, and a Flash memory unit 90. The inventive scheme is realized inside the Flash memory unit 90. It comprises a combined error correction encoder/decoder 82 (and probably other controlling circuitry) that is connected, via a Flash data bus, to a Flash memory 81. The Flash data bus comprises bit lines 86 and 87. The microprocessor 84 can write data, via the bus 91, into the Flash memory 81. These data are encoded by the encoder/decoder 82 (before being programmed into the Flash memory 81). The redundancy bits are programmed, via the bit lines 86, into the Flash memory 81 and the Flash data word is programmed, via the data lines 87, into the Flash memory 81. The encoder/decoder 82 generates a Flash data word having two sections. The first section represents the bit changes and the second section represents the actual data. For this purpose the data line 87 is subdivided into data lines 88 carrying the first section of the Flash data word and data lines 89 carrying the actual data word.

The encoder/decoder 82 comprises a plurality of gates (such as AND-gates, OR-gates, and X-OR-gates).

When reading data from the Flash memory 81, the respective data are fetched via the data lines 86 and 87. Then, an algorithm is applied to check whether the data are valid or invalid. If the data are deemed to be valid, they are made available, via the bus 91, to the microprocessor 84. If the data are deemed to be invalid, they are corrected and then made available, via the bus 91, to the microprocessor 84.

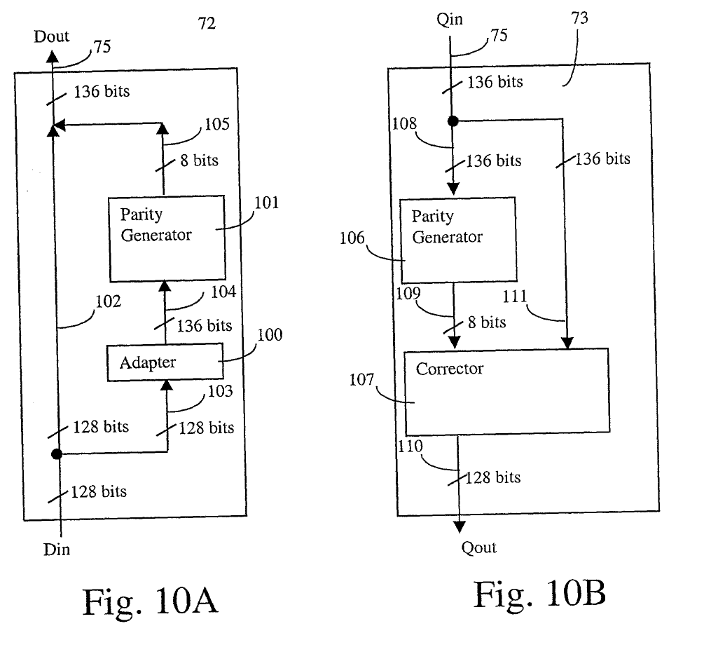

Details of the error correction encoder 72 are illustrated in FIG. 10A. In the present example, an input bus Din for writing data into the Flash memory 71 is 128 bits wide. A 128-bit data word is fed via bus line 103, to an adapter 100. The adapter expands the data word so that it has 136 bits on the output bus 104. This can be done by adding logic zeros at the end of the data word. The 136 bit data word is fed, via the bus 104, to a parity generator 101. This parity generator 101 applies a coding scheme (e.g., based on the Hamming Code) in order to generate the redundancy bits that correspond to the data word at the input Din. In the present example there are 8 redundancy bits which are provided on the output bus 105 of the parity generator 101. The 8-bit redundancy word and the 128-bit data word at the input Din are combined so as to form a 136-bit word on the output bus 75 (Dout). This 136-bit word is stored in the Flash memory 71 for later retrieval.

Details of the error correction decoder 73 are illustrated in FIG. 10B. When a 136-bit word is fetched from the Flash memory 71, it is fed, via the bus 108, into another parity generator 106. This parity generator 106 may be identical to the parity generator 101. The parity generator 106 applies a coding scheme (e.g., based on the Hamming Code) in order to be able to determine whether any of the bits of the 136-bit word is to be corrected and to identify which bit has to be corrected. In the present example, the parity generator 106 provides an 8-bit word on the output bus 109 that indicates whether any of the bits of the 136-bit word is to be corrected and which bit has to be corrected. A corrector unit 107 is employed to perform the necessary correction of the 136-bit word being applied on its input bus 108. The corrected data word (Qout) is then provided on the output bus 110.

The error correction encoder 72 and the error correction decoder 73 can both be implemented using standard digital logic. Preferably, both functional blocks 72 and 73 can be integrated on the same die as the Flash memory 71.

The Flash memory in accordance with the present invention is characterized in that the data are logically organized in the manner illustrated in FIG. 5. Each Flash data word comprises a first section in which information is stored that is reserved for single bit changes. The second section of the Flash data word comprises the actual data. A third section is provided which is used for storing redundancy bits. These redundancy bits are calculated based on the information in the first and second section. An appropriate code (e.g., Hamming code) is employed for the calculation of the redundancy bits.

According to one embodiment of the present invention, certain code requirements of the error correction code can be defined. A first condition would be that the code should be symmetrical, i.e., the code words where all bits are ‘0’ or where all bits are ‘1’ must be legal words.

The following equation may be used to generate the word ParGenQ on the output bus 109 of the parity generator 106:

ParGenQ=H·c^{T}

ParGenQ is the 8-bit result vector on the bus 109. It is generated by multiplication of a parity matrix H by the 136-bit word on the input bus 108. The parity generator 106 implements the matrix H.

On the input side of the Flash memory 71, the same matrix H can be used to generate the redundancy word on output bus 105.

One may define rules that characterize a parity matrix H for use in connection with the present invention. These rules may vary from application to application.

It is to be noted that the present invention does not allow unrestricted bit alterability as in the case of Flash memory used without any error correction.

A cost-effective approach to emulating an electrically erasable programmable read only memory (EEPROM) in Flash memory is presented. The method presented herein uses standard Flash memory components with an improved bit alterability on Flash data words that is sufficient for most applications.

According to another embodiment, for example, the Flash data word has a size of 128 bits and the redundancy word has a size of 8 bits.

The present invention is well suited for use in personal digital assistants (PDAs), cellular phones, digital photo cameras, palm tops and many other devices. A system comprising a Flash memory in accordance with the present invention is well suited for storing web addresses, memos, new address information (e.g., new phone numbers), counters (e.g., fees), etc.

An example in which the present invention can be used is a voice-activated (voice coding) cellular phone. The respective voice samples, for example, are stored in the Flash memory.

The present invention is also well suited for use in a cellular phone where the phone numbers are stored in a Flash memory rather than on a SIM card. If a phone number changes, the old phone number has to be marked as being outdated. For this purpose, the respective data word in the Flash memory has to be marked as being invalid. In order to do this, one single bit has to be altered. In a conventional Flash memory with error correction this is not possible. Using the present invention, however, a single bit can be altered, provided that the new data word (where the one bit is altered) and the original data word have the same redundancy word.

It is an advantage of the present invention that it improves the reliability of any computing device without adding much overhead or cost for additional circuitry.

It is appreciated that various features of the invention which are, for clarity, described in the context of separate embodiments may also be provided in combination in a single embodiment. Conversely, various features of the invention which are, for brevity, described in the context of a single embodiment may also be provided separately or in any suitable sub-combination.

In the drawings and specification preferred embodiments of the invention have been set forth and, although specific terms are used, the description thus given uses terminology in a generic and descriptive sense only and not for purposes of limitation.

1. A system comprising a microprocessor (74; 84), a data bus (75; 91) for writing data into a Flash memory device (71, 72, 73; 90) and a data bus (75; 91) for reading data from the Flash memory device (71, 72, 73; 90), the Flash memory device (71, 72, 73; 90) comprising:
an error correction encoder (72; 82);
a Flash memory (71; 81);
an error correction decoder (73; 82); and
a Flash data bus (75; 86, 87) for interconnecting the error correction encoder (72; 82), the Flash memory (71; 81) and the error correction decoder (73; 82);
the data, upon processing by the error correction encoder (72; 82), being converted into a word comprising a status word (51), a data word (52), and a redundancy word (53).

2. A system as claimed in claim 1, wherein the error correction encoder (72; 82) comprises logic circuitry that represents an error correction code.

3. A system as claimed in claim 2, wherein the error correction code is a symmetric Hamming code.

4. A system as claimed in claim 1, 2 or 3, wherein the Flash data bus (75) comprises bit lines (76; 86) for writing the redundancy word (53) into the Flash memory (71; 81) and/or bit lines (76; 86) for reading the redundancy word (53) from the Flash memory (71; 81).

5. A system as claimed in claim 1, 2 or 3, wherein the Flash data bus (75) comprises bit lines (79; 89) for writing the data word (52) into the Flash memory (71; 81) and/or bit lines (79; 89) for reading the data word (52) from the Flash memory (71; 81).

6. A system as claimed in claim 1, 2 or 3, wherein the Flash data bus (75) comprises bit lines (78; 88) for writing the status word (51) into the Flash memory (71; 81) and/or bit lines (78; 89) for reading the status word (51) from the Flash memory (71; 81).

7. A system as claimed in one of the claims 1-6, wherein the information stored in the redundancy word (53) is usable by the error correction decoder (73; 82) to detect and correct a possible error in the data word (52).

8. A system as claimed in one of the claims 1-7, providing for a bit alterability on the data words that are stored in the Flash memory device (71, 72, 73; 90).

9. A system as claimed in one of the preceding claims, wherein the data that are to be programmed into the Flash memory device have 128 bits, the redundancy word has 8 bits, the data word has 112 bits, and the status word has 16 bits.

10. A system as claimed in one of the preceding claims, wherein the status word (51) determines whether the data word (52) in the data word (52) are valid.

11. A system as claimed in claim 2, wherein the error correction code is a cyclic redundancy code.

12. A system as claimed in one of the preceding claims, wherein the data are organized in three sections in the Flash memory (71; 81), where the first section (51) contains a status word, the second section (52) a data word, and the third section (53) a redundancy word.

13. A system as claimed in one of the preceding claims, wherein the error correction encoder (72; 82) comprises an adapter (100) for expanding the width of the data, and a parity generator (101) for generating the redundancy word (53).

14. A system as claimed in one of the preceding claims, wherein the error correction decoder (73; 82) comprises a parity generator (106) for generating and feeding a word (ParGenQ) to a corrector unit (107).

15. A system as claimed in claim 14, wherein the corrector unit (107) uses the word (ParGenQ) in order to correct a data word read from the Flash memory (71; 81).

16. A method for storing data in a Flash memory device (71; 81), comprising the steps, of:
feeding the data to a parity generator (101),
generating a redundancy word (53) at an output (105) of the parity generator (101),
generating a status word (51),
combining the data (52) and the redundancy word (53) and the status word (51) into one word, and
writing the one word into the Flash memory device (71; 81).

17. A method as claimed in claim 16, wherein the status word of a particular word in the Flash memory device (71; 81) may take on one of a plurality of predefined values without the redundancy word of the particular word having to be changed.

18. A method as claimed in claim 17, wherein the plurality of predefined values are so-called magic words.

19. A method as claimed in one of the claims 16-18, wherein a particular word is read from the Flash memory device (71; 81) and processed by a parity generator (106) in order to detect bit errors.

20. A method as claimed in claim 19, wherein the parity generator (106) generates an output word that indicates whether a bit error has occurred and which bit in the word has to be corrected.

21. A method as claimed in claim 19, wherein a correction takes place based on the information comprised in the output word of the parity generator (106).

22. A method as claimed in one of the claims 16-21, wherein the status word (51) is used to indicate whether that data in the corresponding data field (52) are valid data or invalid data.
